(19) United States
(12) Patent Application Publication
(10) Pub. No.: US 2009/0211690 A1
(43) Pub. Date: Aug. 27, 2009

(54) Rapid Prototyping of Microstructures Using a Cutting Plotter

(76) Inventors: Daniel A. Bartholomeusz, Poway, CA (US); Ameya Kantak, Sunnyvale, CA (US); Sung Lee, Pleasanton, CA (US); Merugu Srinivas, Salt Lake City, UT (US); Himanshu Sant, Salt Lake City, UT (US); Ronald W. Boutte, Clearfield, UT (US); Bruce Gale, Taylorsvile, UT (US); Charles Thomas, Salt Lake City, UT (US)

Correspondence Address: THORPE NORTH & WESTERN, LLP., P.O. Box 1219, SANDY, UT, 84091-1219, US

(21) Appl. No.: 11/887,803

(22) PCT Filed: Apr. 7, 2006
(86) PCT No.: PCT/US2006/012899

§ 371 Date: Dec. 16, 2008

Related U.S. Application Data
(60) Provisional application No. 60/669,570, filed on Apr. 8, 2005.

(51) Int. Cl. B32B 38/10; C23C 16/44; C23C 14/34; C25D 5/02; B29C 33/40; B32B 38/00; G05B 15/00; B26D 7/10; B26D 7/12

(52) U.S. Cl. 156/64; 156/248; 427/248.1; 204/192.1; 205/118; 264/220; 700/275; 83/171; 83/174

(57) ABSTRACT

A method for making a microstructure includes: providing a film (100) on a release liner (110); feeding the film through a cutting plotter (10); cutting the film with a knife blade (34) of the cutting plotter to form a microstructure pattern; peeling the microstructure pattern from the release liner; and transferring the microstructure pattern to a substrate (170). The cutting plotter for making microstructures includes a knife head with a knife blade disposed adjacent a feed mechanism (20), a motor (42) and control system coupled to the knife head for selectively moving the knife head in relation to the film, and the control system and the knife head having an addressable positioning resolution less than approximately 10 μm.

### BACKGROUND

1. Field of Invention

The present invention relates generally to rapid prototyping of microstructures using a cutting plotter. More particularly, the present invention relates to rapid prototyping of microstructures using a plotter with a knife blade head.

2. Related Art

Two dimensional and three dimensional microfabrication techniques have been developed for microfluidic and microelectromechanical systems (MEMS) for scientific, industrial, and biomedical applications. Early microfabrication methods used integrated circuit fabrication techniques used in producing semiconductors. However, complicated fabrication processes, bonding difficulties, and brittleness of semiconductor material have motivated alternative microstructure fabrication techniques and rapid prototyping processes.

Some of these alternative commercial rapid prototyping methods for fabricating microstructures include: micromolding in polydimethylsiloxane (PDMS), laser ablation, stereo lithography, micropowder blasting, hot embossing, micromilling, and the like. Due to its simple fabrication and bonding techniques, micromolding in PDMS has become a common prototyping microfluidic method in the laboratory environment.

Micromolded PDMS structures are typically made by casting the PDMS on photolithographically patterned photoresist. However, PDMS molded microstructures can only have aspect ratios ranging from 0.05 to 2 unless the PDMS is supported. Additionally, patterning microstructures in PDMS micromolding requires standard photolithographic masks, chemicals, and procedures which involve long pre and post bake development steps, and any design change requires a repeat of the long photolithographic process. Alternative photomasks with features down to 15 μm have been used to shorten prototyping time to less than 24 hours, but the rate limiting step is still the photolithographic process.

Other prototyping methods such as micropowder blasting and laser ablation directly build microstructures without photolithography. Micro-powder blasting is capable of producing features >100 μm in hard materials, such as glass, with aspect ratios up to 1.5. Laser ablation produces features on the order of sub-microns (nm), with an aspect ratio up to 10. Channels made by these methods are sealed with adhesive films, PDMS layers, or anodic bonding. Stereo lithography also builds microstructures directly, with micro-meter (μm) feature sizes and aspect ratios up to 22. However, these techniques require expensive fabrication equipment which makes it difficult for in-house prototyping.

Many features for microfluidic applications do not necessarily need the high resolution capabilities used by these fabrication techniques. For example, micropumps, microvalves, microsensors, microfilters, microreactors, microanalysis systems, micro-needles and microfluidic channels all have dimensions well above the resolution capabilities of IC, micro blasting, and laser ablation fabrication techniques. However, these time consuming and expensive techniques are currently the only methods available for producing such structures.

Hence, a rapid and inexpensive microfabrication technique that can directly create microstructures, without photolithographic processes or chemicals and expensive production equipment, has long been sought in the field of microstructure rapid prototyping.

### SUMMARY

It has been recognized that it would be advantageous to develop a microstructure rapid prototyping method and device that can directly create microstructures without photolithographic processes or chemicals. Additionally it has been recognized that it would be advantageous to develop a method for rapidly creating microstructures or microstructure prototypes using a relatively inexpensive cutting plotter to cut a microstructure into a thin film.

The present invention provides for a micro knife plotter device for making microstructures. The plotter device includes a feed mechanism for feeding a film through the plotter device. A knife head with a knife blade can be disposed adjacent the feed mechanism. The knife head can move laterally across the film as the film is fed through the plotter device. A motor and control system can be coupled to the knife head and can selectively move the knife head in relation to the film. The control system and the knife head can have an addressable positioning resolution less than approximately 10 μm.

The present invention also provides for a method for making a microstructure including providing a film having a thickness between approximately 5 μm and 1000 μm. The film can be disposed on a release liner. The film can be fed through a cutting plotter. The film can be cut with a knife blade of the cutting plotter to form a microstructure pattern. The microstructure pattern can be peeled from the release liner. The microstructure pattern can be transferred to a substrate.

Additional features and advantages of the invention will be apparent from the detailed description which follows, taken in conjunction with the accompanying drawings, which together illustrate, by way of example, features of the invention.

### BRIEF DESCRIPTION OF THE DRAWINGS

FIG. 1 is a perspective view of a knife cutting plotter device in accordance with an embodiment of the present invention;

FIG. 2 is a perspective view of a knife head of the cutting plotter device of FIG. 1;

FIG. 3 is a perspective view of a knife blade attached to the knife head of FIG. 2;

FIG. 4 is a perspective view of a knife blade of the knife head of FIG. 2;

FIG. 5 is a perspective view of a knife blade of the knife head of FIG. 2;

FIG. 6 is a top schematic view of a stepper motor of the knife head of FIG. 2;

FIG. 7 is a side schematic view of the stepper motor of FIG. 6, shown with a knife blade attached;

FIG. 8 is a perspective view of a pouncer tool attached to the knife head of FIG. 3;

FIG. 9 is a perspective view of a barbed hook knife blade attached to the knife head of FIG. 3;

FIGS. 10-13 illustrate a method for forming a microstructure using the knife head of FIG. 2;

FIG. 14 is a perspective view of a micro structure mold negative formed in accordance with an embodiment of the present invention;

FIG. 15 is a perspective view of a micro structure mold positive formed in accordance with an embodiment of the present invention;

FIG. 16 is a perspective view of a microstructure channel formed in accordance with an embodiment of the present invention;

FIG. 17 is a perspective view of a microstructure stacked labyrinth formed in accordance with an embodiment of the present invention;

FIG. 18 is a perspective view of a microstructure double T-section in accordance with an embodiment of the present invention;

FIG. 19 is a perspective view of a microstructure enzyme well array in accordance with an embodiment of the present invention;

FIGS. 20a-i are examples of microstructure channels created with the cutting plotter device of FIG. 1;

FIGS. 21a-j are examples of positive microchannels, negative microchannels, and serpentine microchannels created with the cutting plotter device of FIG. 1;

FIGS. 22a-e are examples of microchannels cut in thermal laminate films with the cutting plotter device of FIG. 1;

FIGS. 23a-d are examples of sealed microchannels with a top seal cut with the cutting plotter device of FIG. 1; and

FIGS. 24a-d are examples of microstructures cut in thin film with the cutting plotter device of FIG. 1.

### DETAILED DESCRIPTION OF EXAMPLE EMBODIMENT(S)

Reference will now be made to the exemplary embodiments illustrated in the drawings, and specific language will be used herein to describe the same. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

U.S. Provisional Patent Application 60/669,570, filed Apr. 8, 2005, is herein incorporated by reference for all purposes.

Generally, the present invention provides for a method and device for fabricating microstructures and microstructure rapid prototypes. The device includes a cutting plotter with a knife head that holds a knife blade that can score or cut a thin film placed in the plotter. The cutting plotter has an addressable resolution below approximately 10 μm, and the knife head provides swivel and tangential knife blade control.

The method for fabricating a microstructure includes placing or feeding a thin film having a thickness between approximately 5 and 1000 μm in a cutting plotter connected to a programmable controller, such as a controller. An image of a microstructure can be sent from the controller to the cutting plotter. The cutting plotter can score or cut a microstructure pattern into the thin film corresponding to the image sent from the computer. The thin film can be removed from the cutting plotter and the unused portions of the microstructure pattern can be removed or “weeded” from the thin film. The remaining microstructure pattern can then be transferred to a substrate where the microstructure pattern can be used in creating a microstructure, a microstructure prototype, a shadowmask, a photolithographic micromachining shadowmask, electroplated channels, a microstructure mold, a laminated micro-fluidic structure, a double-T intersection, enzyme reaction wells, enzyme reaction wells for an enzyme based biosensor, and the like.

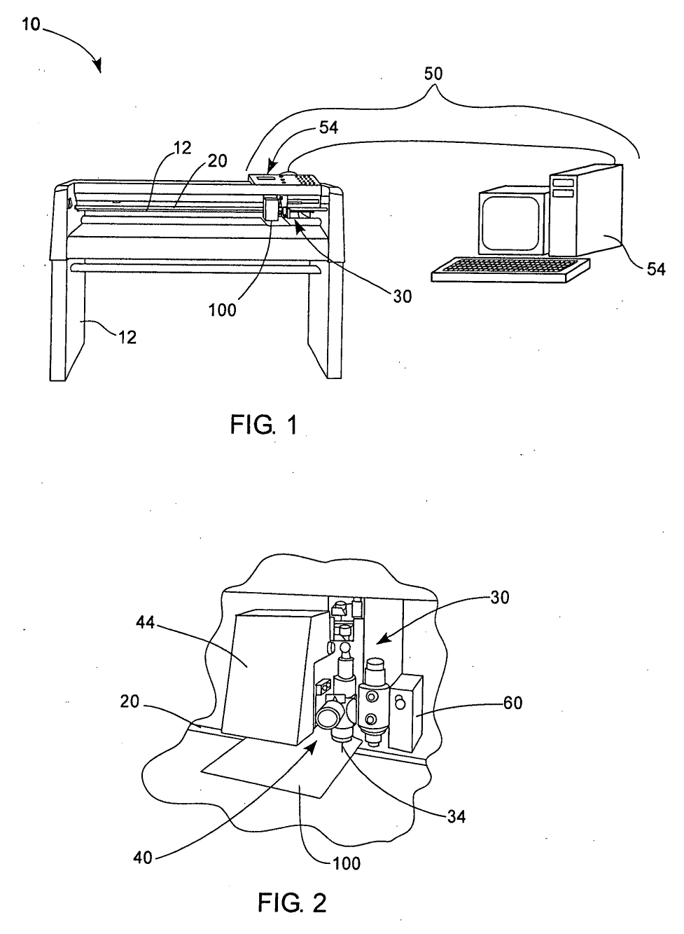

As illustrated in FIGS. 1-2, a micro knife cutting plotter device, indicated generally at 10, is shown for making microstructures in accordance with an embodiment of the present invention. The cutting plotter device 10 can include a frame 12 with a feed mechanism 20 coupled to the frame for feeding a film 100 through the plotter device 10. In one aspect, the feed mechanism 20 can include friction rollers 22 to move the film 100 through the plotter device 10. The feed mechanism 20 can also include other film moving elements such as sprocket feed spools, static rollers, or the like, to assist in moving the film 100 through the plotter device 10.

The plotter device 10 can also include a knife head, indicated generally at 30. The knife head 30 can be disposed adjacent the feed mechanism 20 and can hold a knife blade 34. The knife head 30 can move laterally across the film 100 as the film is fed by the feed mechanism 20 through the plotter device 10 in order to move the knife blade 34 across the film 100.

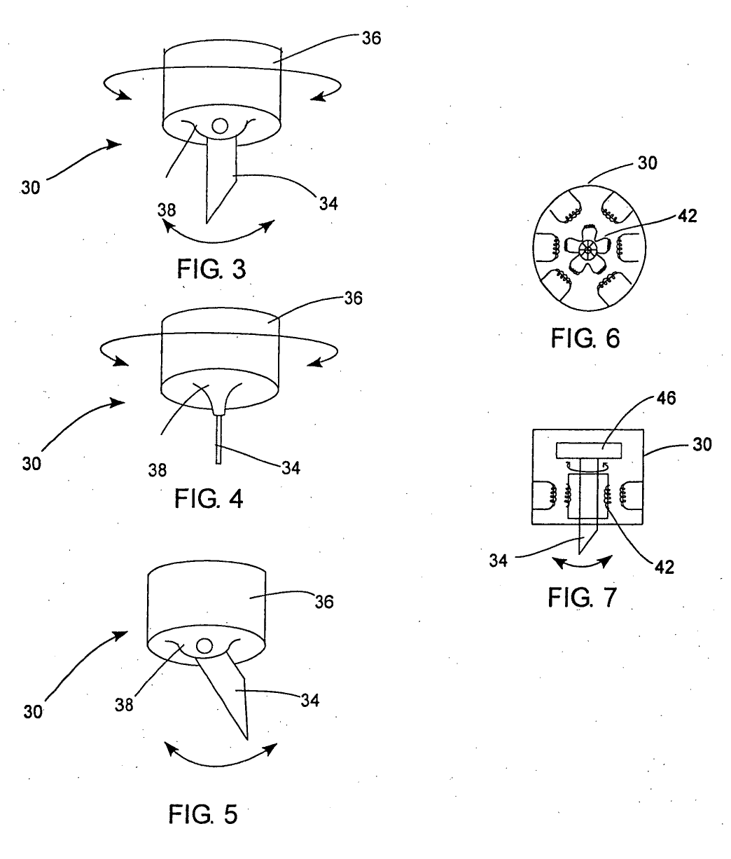

Referring to FIGS. 3-5, the knife head 30 can swivel in order to turn the knife blade 34 in relation to the film 100. It will be appreciated that swivel control assists in making rounded or circular cuts. In one aspect, the knife head 30 can include a controllable swivel mount 36 coupling the knife blade 34 to the knife head 30.

The knife head 30 can also tilt or pivot the knife blade 34 with respect to the film 100 in order to allow the blade 34 to contact the film 100 at selectable angles with respect to the film 100, thereby providing tangential blade control. It will be appreciated that tangential blade control assists making rectangular cuts. Blade angle can be measured from the surface of the film material to the blades' cutting edge. Blade angle and depth determine the amount of uncut material between the blades leading edge. Blade depth can be controlled by controlling the force of the blade on the film. Thus, the knife head 30 can include a pivotal mount 38 that can couple the knife blade 34 to the knife head 30 and position the knife blade 34 at selectable angles with respect to the film 100.

Referring to FIGS. 6-7, a stepper motor 42 can be coupled to the knife head 30 for selectively holding the knife blade 34 and selectively releasing the blade 34 to allow swiveling. Thus, the knife blade 34 can be rotated with respect to the film 100, and also moved laterally across the film 100 as the film is fed by the feed mechanism 20 through the cutting plotter. In this way the knife blade 34 can cut a pattern at any location on the film.

The stepper motor 42 can also control the angle of the knife blade 34 with respect to the film 100 and an absolute encoder 46 can provide feedback for precise blade angle position. In use, the stepper motor 42 can hold the blade 34 in a selected angular position with respect to the film when the stepper motor is powered on, and can release the blade to allow swivel cutting when powered off.

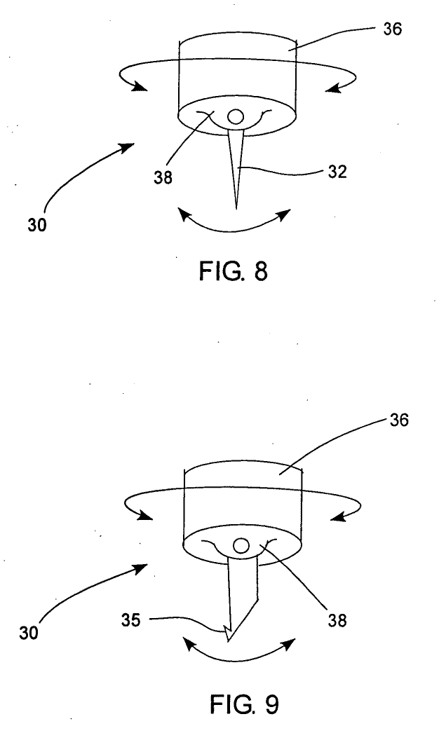

Referring to FIG. 8, the knife head 30 can also include a pouncer tool 32 such as a heatable tapered needle. The pouncing tool can form holes in the film 100. A heated needle can puncture or melt a hole in the material and the taper on the needle can determine the size of the hole by varying the depth the needles is inserted or “pounced” through the film. It will be appreciated that a separate pouncing needle can be provided, a heated knife can be provided, or a tapered knife can be provided.

Referring to FIG. 9, the knife head 30 can also include barbed hooks 35 that can engage selectable portions of cut film. The barbed hooks 35 can automatically weed the un-needed portions of the film before the film 100 is removed from the plotter 10.

Returning to FIGS. 1-2, a motor system, indicated generally at 40, including the stepper motor 42 described above, can be coupled to the knife head 30 to selectively move the knife head in relation to the film 100. The motor system 40 can also include a motor 44 to move the knife head 30 laterally across the feed mechanism 20 and hence the film 100.

A control system, indicated generally at 50, can be coupled to the motor system 40 to actuate the motor system 40 and selectively move the knife head 30 in relation to the film 100. The control system 50 can include a programmable user interface 52 coupled to the cutting plotter device 10. The control system 50 can also be coupleable to a separate programming device, such as a computer 54. Thus, the control system 50 can receive instruction from a computer 54 to drive the motor system 40 and selectively position the knife blade 34 as the feed mechanism 20 moves the film 100 through the cutting plotter device 10. The control system 50 can include features such as importing CAD drawings, controlling direction of cut, defining channels, defining weed areas, setting blade angle, setting blade or needle temperature, adding layered visualization, and the like.

The control system 50 and the knife head 30 can have an addressable resolution less than approximately 10 μm. It will be appreciated that the resolution or accuracy of cutting plotters can be specified in terms of mechanical and addressable resolution. The mechanical resolution specifies the resolution of the motors, while the addressable resolution is the programmable step size. Additionally, the repeatability of the cutting plotter 10 can be specified as the quantitative measure of the machine's ability to return to the exact point where a cut initiated, such as occurs when cutting a circle. Thus, it is a particular advantage of the cutting device 10 of the present invention that the addressable resolution of the controller is less than approximately 10 μm. Achieving this level of addressable resolution can be accomplished by retrofitting existing cutting plotter devices with higher resolution encoder scales in the controller devices so as to more accurately position the knife head.

The cutting plotter device 10 can use different blades for various film materials. Specifically, the knife head 30 can have a plurality of interchangeable knife blades 34 including a straight blade, a serrated blade, zester-type blade for cutting rounded channels, a roller type blade, or the like. Other specialty shaped blades, as known in the art, can also be used with the knife head of the present invention. The knife blades 34 can also have plurality of thicknesses including a thickness of less than approximately 5 μm.

Additionally, the knife blade 34 can be electrically coupled to a power source to heat the knife blade 34. The controller 50 can control the temperature of the heated blade. It will be appreciated that a heated blade can cut some film materials, such as plastic, faster by slightly melting the film during the cut. Advantageously, heating the knife also smooths the walls of the cut by annealing the cut. Smooth walls reduce surface tension affects in microfluidic applications.

Additionally, the knife blade 34 can have an automatic blade alignment and sharpener device, indicated generally at 60. It will be appreciated that the knife blades can dull quickly when cutting harder materials. Thus, the automatic sharpener 60 can extend the life of the blade, and reduce maintenance down time of the cutting plotter device 10. In one aspect, the blade sharpener 60 can include a mechanical grinding device. In another aspect, the blade sharpener 60 can be an electrochemical etching process. Other blade sharpening devices and methods can also be used to maintain the cutting edge of the knife blade.

The film 100 used in the cutting plotter device 10 to form the microstructure can be a thin film having a thickness between approximately 5-1000 μm. It will be appreciated that film thicknesses required for microstructures are well beyond the thicknesses of materials used for typical graphic arts applications. Thus, typical cutting plotters, as used in the graphic arts industries, don't have high enough resolution or accuracy to cut microstructures in thicker films, nor in the thin films of the present application. Consequently, it is a particular advantage of the present invention that films as thin as 5 μm can be fed into and accurately cut by the cutting plotter device 10 without damaging or destroying the film in the cutting process.

Additional advantages of cutting thin films with the cutting plotter device 10 of the present invention include elimination of expensive equipment, process chemicals and production time. Specifically, the cutting the film 100 in the cutting plotter device 10 allows for fabrication of microstructures without a clean room, photolithographic pattern generators, UV mask aligners, photo exposing devices and chemicals, or the like. Additionally, this method eliminates pre and post bake procedures, as well as complicated exposure and development procedures required for traditional photolithography fabrication methods previously used.

Accordingly, the film 100 can be any material formable into a thin film that can be fed into the feed mechanism 20 of the cutting plotter device 10. For example, the film 100 can be a conductive film such as a hydrogel, a filter, insulative, piezoelectric, pyroelectric, a Polyvinylidene difluoride (PVDF) film, and the like. Thus, in one aspect, the film 100 can be a hydrogel forming a gel layer that is responsive to thermal, electrical or chemical changes. In another aspect, the film can be a hydrogel responsive to enzymes, PCR/DNA sequencing, electrophoresis, biochemical/antibody, or filters and the like.

Additionally, the film 100 can be a material that is relatively soft and hardenable by thermal, ultraviolet (UV) or adhesive curing. For example, the film 100 can be an ultraviolet curable film with an ultraviolet curable adhesive, or a biogel film with internally isolated hydrophobic and hydrophilic regions. The film 100 can also be a metal film suitable for use in a cutting plotter.

The film 100 can also have an adhesive backed release liner 110 to facilitate placement on a substrate surface. The adhesive backed release liner 110 can include a degradable adhesive so the adhesive will not interfere with the microstructure fabricated by the cutting plotter.

Advantageously, both production grade components cut directly by the plotter, and prototype components can be fabricated using the method and device of the present invention. In the case of production grade components, bulk micromachining can be realized that can produce large quantities of microstructures with significant equipment, manpower, and process time reductions. In the case of rapid prototyping, this method and device can be combined with existing computerized numerical control (CNC) systems to define and produce experimental three dimensional prototypes from CAD files.

For example, a 3D solid structure can be created by defining microchannel geometry using 3D CAD software. The 3D CAD model can be sliced into multiple layers, producing 2D cross sectionals of the microchannel in a polymer film. The cutting plotter device 10 can be used to cut a polymer film according to each of the 2D cross sectionals of the CAD model. Microchannels of varying aspect ratios can then be produced by layering on the adhesive tapes on substrates, such as glass, platinum, gold, graphite, PDMS, or the like.

Accordingly, the present invention can be used to fabricate microchannels, or complex microstructures with a variety of geometries (2D or 3D) by using the cutting plotter 10 in conjunction with a 3D software. The method can be extended to various polymer films and thinner sheets, such as PDMS, PMMA or anything that can be micromolded, to fabricate microchannels. The invention can also be used to make sterile biocompatible microchannels in predefined geometries that can be used in pharmaceutical and biochip applications, and in making microchannels for a field flow fractionation device for separating nanoparticles and proteins. The microchannels prepared from this technique can be successfully employed and characterized on different substrates including but not limited to glass, platinum, gold, graphite and PDMS.

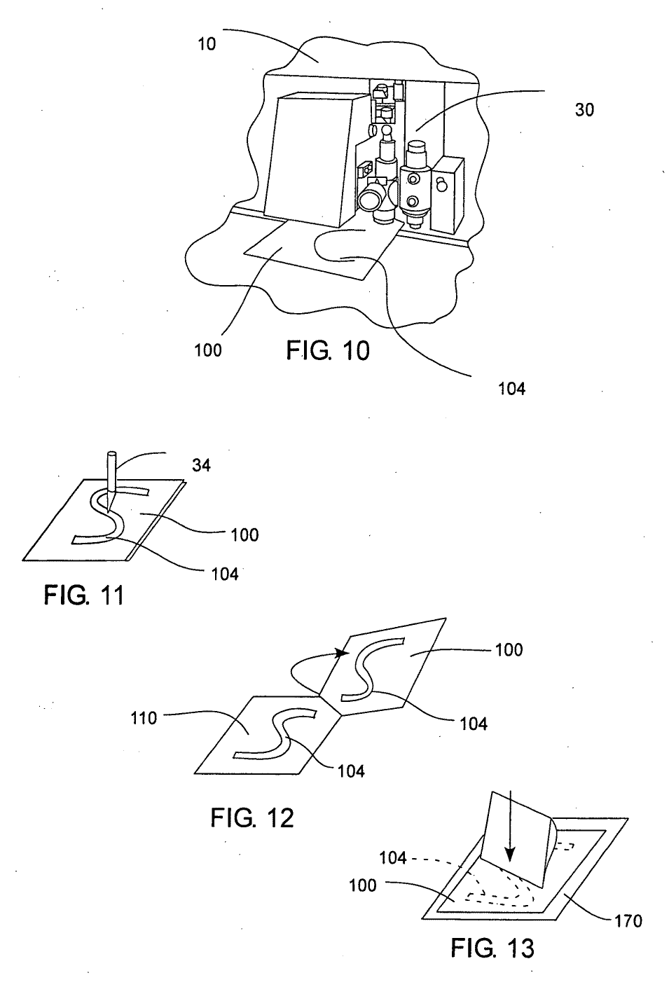

Thus, as described above, and illustrated in FIGS. 10-13, the present invention provides for a method for making a microstructure including providing a film having a thickness between approximately 5 μm and 1000 μm. The film can be disposed on a release liner. The film 100 can be fed through a cutting plotter 10 as shown in FIG. 10. The film can be cut with a knife blade of the cutting plotter to form a microstructure pattern 104, as shown in FIG. 11. The microstructure pattern 104 can be peeled from the release liner 110, as shown in FIG. 12. The microstructure pattern 104 can be transferred to a substrate 170, as shown in FIG. 13.

The step of peeling the microstructure from the release liner can also include weeding unwanted portions of the cut microstructure pattern from the cut film to form an unweeded layer of film. The unweeded layer can then be transferred to another substrate to function as a physical barrier or shadow mask.

The step of transferring the microstructure pattern can also include applying application tape to the pattern. The application tape can be peeled along with the pattern from the release liner. The application tape can then be pressed with the pattern onto a substrate.

The method for making a microstructure can also include curing the film. The pattern can then be used as a mold pattern, waveguide or mechanical structure.

The present invention also provides for a method for forming an electroplated structure including providing a film on a release liner. The film can be fed through a cutting plotter. The film can be cut with a knife blade of the cutting plotter to form a channel microstructure pattern with channel openings. Unwanted portions of the pattern can be weeded from the cut film to form an unweeded layer of film. The unweeded layer can be transferred to another substrate to function to form a physical barrier or shadow mask. The channel openings can be covered. A seed layer and a gold layer can be deposited over the channel. The channel openings can be uncovered. The substrate can be placed in a copper sulfate solution and a current density can be applied to form a copper deposition layer. The pattern can be removed from the solution leaving an electroplated structure. The electroplated structure can form hollow electroplated channels.

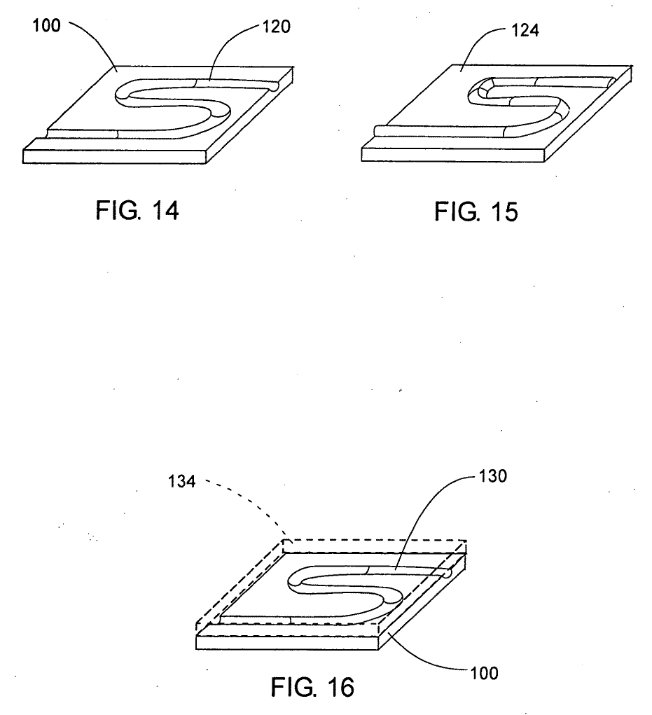

Referring to FIGS. 14-15, the present invention also provides for a method for forming a micromold including providing a film 100 on a release liner. The film can be fed through a cutting plotter. The film can be cut with a knife blade of the cutting plotter to form a negative microstructure pattern. Unwanted portions of the cut film can be weeded to form a pattern in the film and mold cavity in the negative. The weeded layer can be transferred to another substrate to function to form a physical barrier or shadow mask 120, as shown in FIG. 14. A mold material can be poured into the negative and the mold material can be cured to form a positive molded microstructure 124, as shown in FIG. 15. The positive molded microstructure can be removed from the mold cavity. The mold material can be a PDMS prepolymer mixed with a curing agent.

Referring to FIG. 16, the present invention also provides for a method for forming a sealed microchannel including providing a film 100 on a release liner. The film can be fed through a cutting plotter. The film can be cut with a knife blade of the cutting plotter to form a channel microstructure pattern 130. The film 100 can be transferred to a substrate, and a top layer 134 can be disposed over the film forming sealed channels. The film can be a vinyl adhesive, static vinyl, or thermal laminate film.

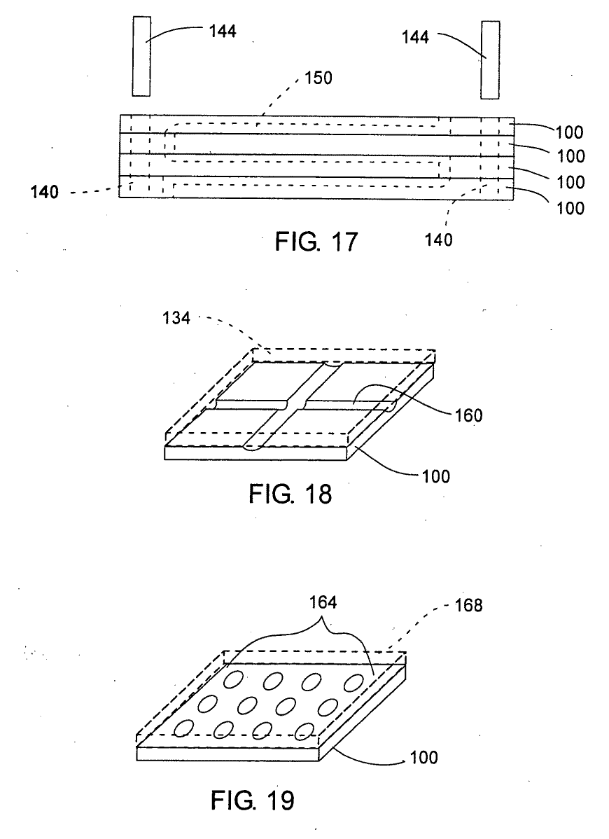

Referring to FIG. 17, the method of forming a sealed microchannel can also include stacking cut film 100 in layers to form the microchannel structure. Additionally, alignment holes 140 can be cut into the film by the cutting plotter and the alignment holes can be aligned when stacking the layers. An alignment device 144 can be inserted into the aligned and stacked holes.

The method of forming a sealed microchannel can also include cutting channels in some portions of the film and holes in other portions of the film. The portions of the film can be aligned and stacked in alternating layers of channels and holes to form a 3D microstructure labyrinth 150.

Referring to FIG. 18, the present invention also provides for a method for forming a microstructure double T-section including providing a film 100 on a release liner. The film can be fed through a cutting plotter. The film can be cut with a knife blade of the cutting plotter to form a double T-intersection microstructure pattern 160. The double T-intersection can have hydraulic diameter down to about 50 μm.

Referring to FIG. 19, the present invention also provides for a method for forming a microstructure enzyme reaction well including providing a film 100 on a release liner. The film can be fed through a cutting plotter. The film can be cut with a knife blade of the cutting plotter to form an array of enzyme reaction well array microstructure pattern 164. Cut portions of the wells can be weeded from the film leaving the well in the film. The film 100 can be transferred to a substrate 168 with the substrate forming a clear window to the wells. The wells can be filled with reagents and luminescent signals from the wells can be measured. The array of wells can also be lyophilized.

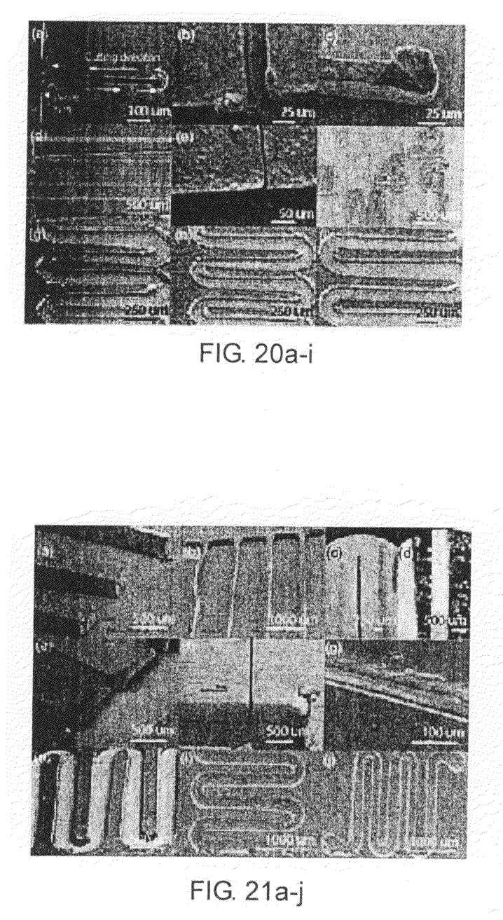

Illustrated in FIGS. 20a-i are examples of microstructures created with the method and device of the present invention. The microstructures illustrated include a 23 μm channel (drawn 10 μm wide) without a fillet, as shown in 20a; the same channel cut with a 50 μm fillet, as shown in 20b; a 25 μm positive structure (drawn 20 μm), as shown in 20c; tapering of a 50 and a 60 μm channel drawn without a fillet, as shown in 20d; a single 6 μm slice, as shown in 20e; a lab logo showing a potential use of positive patterns, as shown in 20f; serpentine channels having a width and spacing drawn at 80 μm as shown in 20g, 100 μm as shown in 20h, and 140 μm as shown in 20i. The examples illustrated in FIGS. 20a-i demonstrate that cut consistency improves as the channel width and spacing increases.

Illustrated in FIGS. 21a-j are examples of positive microchannels, negative microchannels, and serpentine microchannels in various films. The microstructures illustrated include 100-80 μm features in 360 μm thick green sandblast, as shown in FIG. 21a; 150-180 μm features in 190 μm thick static vinyl, as shown in FIG. 21b; 250 μm features in 91 μm thick adhesive backed aluminum, as shown in FIG. 21c; 500 μm feature in 110 μm thick filter paper (on black carbon tape), as shown in FIG. 21d; 120-100 μm channels in 190 μm thick static vinyl, as shown in FIG. 21e; 40 μm single slice in 1000 μm thick tan (rubber) sandblast mask, as shown in FIG. 21f; 32 μm groove in 100 μm thick calendered vinyl, as shown in FIG. 21g; 150 μm channels in 75 μm thick clear vinyl, as shown in FIG. 21h; and 180 μm channels in 75 μm thick cast vinyl. (j) 200 μm channels in 70 μm thick polyester, as shown in FIG. 21i.

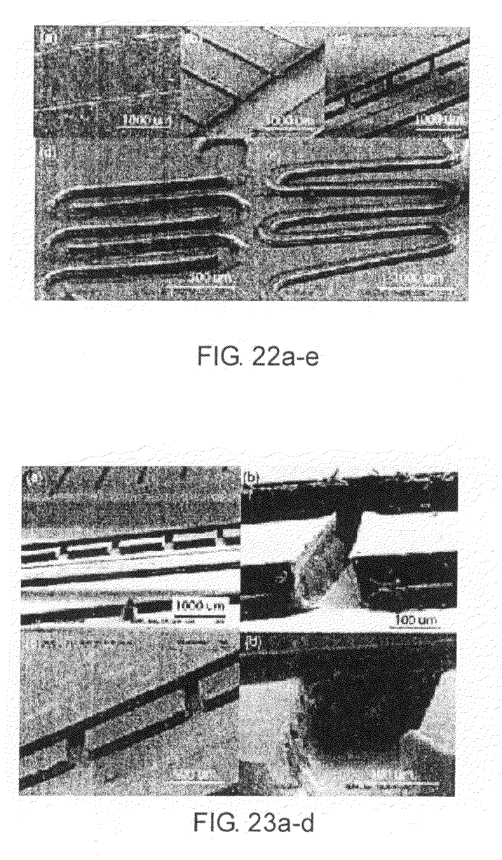

Illustrated in FIGS. 22a-e, are examples of microchannels cut in thermal laminate films. The microstructures illustrated include 50 and 60 μm channels in 25 μm thick thermal transfer, as shown in FIG. 22a. The channels in FIG. 22a were inconsistent because the adhesive melted into the channels. Also illustrated are 90-60 μm channels in 5 mil thermal laminate film, as shown in FIG. 22b; 230-250 μm channels in 10 mil laminate and sealed with another layer of 10 mil laminate, as shown in FIG. 22c; 120 μm serpentine channel in 3 mil thermal laminate film, as shown in FIG. 22d; and a positive 250 μm serpentine channel in 5 mil laminate film, as shown in FIG. 22e.

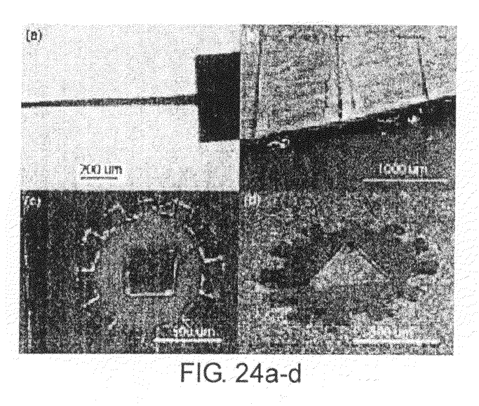

Illustrated in FIGS. 23a-d are examples of sealed microchannels with a top seal. In FIGS. 23a-b, adhesive and polyester layers can be seen in 5 mil thermal laminated channels. Since the channels were cut from the adhesive side, they are slightly narrower at the top then they are at the bottom. In FIGS. 23c-d, sealed channels in 75 μm thick clear adhesive vinyl are shown.

Illustrated in FIGS. 24a-d, is an example of Silicon traces sputtered onto a glass slide using a shadow mask, as seen in FIG. 24a. FIG. 24b shows an example of copper channels electroplated using a sacrificial layer. The channel walls were destroyed during handling of the sample. Also illustrated are examples of a negative 1 mm diameter gear with 100 μm teeth, as shown if FIG. 24c; and a positive gear electroplated with a mask, as shown in FIG. 24d.

Various aspects of the methods and apparatus described above are further described in U.S. Provisional Patent Application No. 60/669,570, filed Apr. 8, 2005, which is herein incorporated by reference.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

What is claimed is:

1. A method for making a microstructure, comprising:
a) providing a film on a release liner;
b) feeding the film through a cutting plotter; and
c) cutting the film with a knife blade of the cutting plotter to form a microstructure pattern;
d) peeling the microstructure pattern from the release liner; and
e) transferring the microstructure pattern to a substrate.

2. A method in accordance with claim 1, wherein the microstructure is selected from the group consisting of a prototype, a shadowmask, a photolithographic micromachining shadowmask, electroplated channels, a microstructure mold, a laminated micro-fluidic structure, a double-T intersection, enzyme reaction wells, enzyme reaction wells for an enzyme based biosensor, and combinations thereof.

3. A method in accordance with claim 1, wherein the film has a thickness between approximately 20-1000 μm.

4. A method in accordance with claim 1, wherein the film is an ultraviolet opaque red emulsion on a clear polyester backing without an adhesive.

5. A method in accordance with claim 1, wherein the film is ultraviolet curable or heat cured pressure sensitive adhesive; further comprising:
a) curing the film; and
b) using the pattern as a mold pattern, waveguide or mechanical structure.

6. A method in accordance with claim 1, wherein the film is a conductive film selected from the group consisting of a hydrogel, a filter, insulative, piezoelectric, pyroelectric, a Polyvinylidene difluoride (PVDF) film, and combinations thereof.

7. A method in accordance with claim 1, wherein the film is a hydrogel forming a gel layer responsive to thermal, electrical or chemical changes.

8. A method in accordance with claim 1, wherein the film is a hydrogel responsive to enzymes, PCR/DNA sequencing, electrophoresis, biochemical/antibody, or filters.

9. A method in accordance with claim 1, wherein the film is relatively soft and hardenable by thermal, UV or adhesive curing.

10. A method in accordance with claim 1, wherein the film has a thickness less than approximately 1 mm.

11. A method in accordance with claim 1, wherein the film is an ultraviolet curable film with an ultraviolet curable adhesive.

12. A method in accordance with claim 1, wherein the film is a biogel film with internally isolated hydrophobic and hydrophilic regions.

13. A method in accordance with claim 1, wherein the film is a polyvinylidene difluoride film.

14. A method in accordance with claim 1, wherein the film is a metal film.

15. A method in accordance with claim 1, wherein the film has an adhesive backed release liner with a degradable adhesive.

16. A method in accordance with claim 1, wherein peeling includes using application tape; and wherein transferring includes pressing the pattern down with a squeegee.

17. A method in accordance with claim 1, further comprising:
a) applying application tape to the pattern;
b) peeling the application tape with the pattern from the release liner; and
c) pressing the application tape with the pattern onto a substrate.

18. A method in accordance with claim 1, further comprising:
a) depositing a layer of material or silicon over the pattern by sputtering or vapor phase deposition or other physical material deposition method;
b) peeling away the pattern leaving channels in the layer of material or silicon.

19. A method in accordance with claim 1, further comprising:
a) weeding unwanted portions from the cut film to form an unweeded layer of film; and
b) transferring the unweeded layer to another substrate to function as a physical barrier or shadow mask.

20. A method in accordance with claim 19, wherein the step of transferring the unweeded layer further comprises peeling the pattern from the release liner.

21. A method in accordance with claim 19, further comprising:
a) cutting channels in the film with the knife blade;
b) weeding the channels from the cut film to form a pattern with channel openings;
c) transferring the pattern to a substrate;
d) covering the channel openings;
e) depositing a seed layer and a gold layer;
f) uncovering the channel openings;
g) placing the substrate in a copper sulfate solution and applying a current density to form a copper deposition layer; and
h) removing the pattern leaving an electroplated structure

22. A method in accordance with claim 19, wherein the electroplated structure forms hollow electroplated channels.

23. A method in accordance with claim 1, further comprising:
a) cutting a negative into the film with the knife blade;
b) weeding the negative of the cut film to form a pattern in the film and mold cavity in the negative;
c) pouring a mold material into the negative and curing the mold material to form a positive molded microstructure; and
d) removing the positive from the mold cavity.

24. A method in accordance with claim 23, wherein the mold material is PDMS prepolymer mixed with a curing agent.

25. A method in accordance with claim 1, further comprising:
a) cutting channels in the film with the knife blade;
b) transferring the film to a substrate; and
c) disposing a top layer over the film forming sealed channels.

26. A method in accordance with claim 25, wherein the film is a vinyl adhesive, static vinyl, or thermal laminate film.

27. A method in accordance with claim 25, where in the step of transferring the film further includes stacking cut film in layers to form the microstructure.

28. A method in accordance with claim 27, further comprising the steps of:
a) cutting alignment holes in the film; and
b) inserting an alignment device through holes in the layers.

29. A method in accordance with claim 27, further comprising the steps of:
a) cutting channels in some portions of the film and holes in other portions of the film; and
b) stacking the cut film in alternating layers of channels and holes.

30. A method in accordance with step 1, wherein the step of cutting the film further includes cutting the film with the knife blade in a double-T intersection.

31. A method in accordance with claim 30, wherein the intersection has a hydraulic diameter down to about 50 μm.

32. A method in accordance with claim 1, further comprising:
a) cutting an array of enzyme reaction wells into the film with the knife blade;
b) removing cut portions of the wells from the film; and
c) transferring the film to a substrate with the substrate forming a clear window to the wells.

33. A method in accordance with claim 32, further comprising the steps of:
a) filling the wells with reagents; and
b) measuring luminescent signals from the wells.

34. A method in accordance with claim 33, further comprising the steps of:
a) lyophilizing the array of wells.

35. A micro knife plotter device for making microstructures, comprising:
a) a feed mechanism for feeding a film through the plotter device;
b) a knife head with a knife blade, disposed adjacent the feed mechanism, and configured to move laterally across the film as the film is fed through the plotter device;
c) a motor and control system, coupled to the knife head, for selectively moving the knife head in relation to the film; and
d) the control system and the knife head having an addressable positioning resolution less than approximately 10 μm.

36. A device in accordance with claim 35, further comprising:
the control system including a knife head providing swivel and tangential knife blade control.

37. A device in accordance with claim 35, wherein the knife blade has a thickness less than approximately 5 μm.

38. A device in accordance with claim 35, further comprising:
a) a controllable swivel mount coupling the knife blade to the knife head;
b) a stepper motor coupled to the knife head for selectively holding the knife blade and selectively releasing the blade to allow swiveling.

39. A device in accordance with claim 35, further comprising:
an absolute encoder wheel for blade angle position feedback.

40. A device in accordance with claim 35, further comprising:
a) a pivotal mount coupling the knife blade to the knife head to position the knife head at selectable angles; and
b) a stepper motor coupled to the knife head to control the angle of the knife blade.

41. A device in accordance with claim 35, wherein the knife blade is electrically coupled to a power source to heat the knife blade.

42. A device in accordance with claim 35, further comprising:
a knife head with a plurality of interchangeable knife blades.

43. A device in accordance with claim 42, wherein the plurality of knife blades are selected from the group consisting of: a zester-type blade, and a roller blade.

44. A device in accordance with claim 35, further comprising:
a knife head with a pouncing tool including a heated tapered needle.

45. A device in accordance with claim 35, further comprising:
barbed hooks configured to engage selectable portions of cut film.

46. A device in accordance with claim 35, wherein the control system includes features selected from the group consisting of importing CAD drawings, controlling direction of cut, defining channels, defining weed areas, setting blade angle, setting blade or needle temperature, adding layered visualization, and combinations thereof.

47. A device in accordance with claim 35, further comprising:
an automatic blade aligner and sharpener.

48. A method for making a microstructure, comprising:
a) providing a film with a thickness between approximately 20-100 μm and disposed on a release liner;
b) feeding the film through a cutting plotter having a controller and an addressable resolution less than approximately 10 μm;
c) cutting the film with a knife blade of the cutting plotter to form a pattern;
d) weeding unwanted portions from the cut film to form an unweeded layer of film; and
e) peeling the pattern from the release liner; and
f) transferring the pattern to a substrate.
